(19) United States
(12) Patent Application Publication
(10) Pub. No.: US 2024/0413080 A1
(43) Pub. Date: Dec. 12, 2024

(54) SEMICONDUCTOR DEVICE AND METHOD FOR PRODUCING SEMICONDUCTOR DEVICE

(71) Applicant: FUJI ELECTRIC CO., LTD., Kawasaki-shi (JP)

(72) Inventor: Naoyuki OHSE, Matsumoto-city (JP)

(73) Assignee: FUJI ELECTRIC CO., LTD., Kawasaki-shi (JP)

(21) Appl. No.: 18/647,654

(22) Filed: Apr. 26, 2024

(30) Foreign Application Priority Data
Jun. 8, 2023 (JP) 2023-094927

(51) Int. Cl. H01L 23/528; H01L 21/3213; H01L 23/29; H01L 23/31; H01L 23/532

(52) U.S. Cl. CPC H01L 23/5283; H01L 21/32133; H01L 23/293; H01L 23/3157; H01L 23/53219; H01L 23/53242

(57) ABSTRACT

A semiconductor device includes: a semiconductor substrate; a first metallic layer provided over the semiconductor substrate; a second metallic layer provided on the first metallic layer; and a protective film including an opening, the protective film being provided on the second metallic layer, in which the protective film is in contact with the second metallic layer, and is made of a resin material, the first metallic layer and the second metallic layer are each provided across a region that includes the opening in plan view, and the second metallic layer has a part interposed between the first metallic layer and the protective film.

### CROSS REFERENCE TO RELATED APPLICATION

This application is based on, and claims priority from, Japanese Patent Application No. 2023-094927, filed on Jun. 8, 2023, the entire contents of which are incorporated herein by reference.

### BACKGROUND

### Technical Field

This disclosure relates to a semiconductor device and to a method for producing a semiconductor device.

### Related Art

Some semiconductor devices, for example, some power semiconductor devices, may include an electrode that is to be coupled by a solder material to a conductor such as a lead or a terminal pin. For example, a semiconductor device described in Japanese Patent Application Laid-Open Publication No. 2019-201160 includes a semiconductor substrate that has a surface provided with an emitter electrode that is to be coupled by a solder material. The emitter electrode includes a first metallic layer, a second metallic layer, and an oxidation barrier layer. On the first metallic layer, a first protective film having a first opening is provided so as to cover an end portion of the first metallic layer. The second metallic layer is provided on the first metallic layer in the first opening. The oxidation barrier layer is provided on the second metallic layer in the first opening.

The semiconductor device described in Japanese Patent Application Laid-Open Publication No. 2019-201160 is provided with a second protective film having a second opening such that the second protective film covers an end portion of the oxidation barrier layer and the first protective film. Thus, it is possible to prevent generation of cracks due to thermal stress caused at a boundary between the first protective film and the second metallic layer.

However, in the semiconductor device described in Japanese Patent Application Laid-Open Publication No. 2019-201160, a part of the first protective film is interposed between the first metallic layer and the second metallic layer. Thus, the semiconductor device has a risk that the second metallic layer may detach from the first metallic layer due to thermal expansion of the first protective film. In addition, not only the first protective film, but also the second protective film, is required, thereby complicating a production process. As a result, the semiconductor device has a disadvantage of an increase in cost.

### SUMMARY

In view of the circumstances described above, an object of one aspect according to this disclosure is to improve reliability of a semiconductor device at low cost.

A semiconductor device according to an aspect of this disclosure includes: a semiconductor substrate; a first metallic layer provided over the semiconductor substrate; a second metallic layer provided on the first metallic layer; and a protective film including an opening, the protective film being provided on the second metallic layer, in which the protective film is in contact with the second metallic layer, and is made of a resin material, the first metallic layer and the second metallic layer are each provided across a region that includes the opening in plan view, and the second metallic layer has a part interposed between the first metallic layer and the protective film.

A method according to another aspect of this disclosure is a method for producing a semiconductor device, the semiconductor device including: a semiconductor substrate; a first metallic layer provided over the semiconductor substrate; a second metallic layer provided on the first metallic layer; and a protective film including an opening, the protective film being provided on the second metallic layer, the method including: forming the first metallic layer and the second metallic layer; and forming the protective film, in which the protective film is in contact with the second metallic layer, and is made of a resin material, the first metallic layer and the second metallic layer are each provided across a region that includes the opening in plan view, and the second metallic layer has a part interposed between the first metallic layer and the protective film.

According to one aspect of this disclosure, it is possible to improve reliability of a semiconductor device at low cost.

### BRIEF DESCRIPTION OF THE DRAWINGS

FIG. 1 is a plan view of a semiconductor device according to a first embodiment;

FIG. 2 is a cross section taken along line A-A′ shown in FIG. 1;

FIG. 3 is an enlarged cross section of a part of the semiconductor device according to the first embodiment;

FIG. 4 is an enlarged cross section of a part of a semiconductor device according to a reference example;

FIG. 5 is a diagram showing a method for producing the semiconductor device according to the first embodiment;

FIG. 6 is a diagram explaining a substrate preparation step;

FIG. 7 is a diagram explaining a first film deposition step included in a metallic layer formation step;

FIG. 8 is a diagram explaining a second film deposition step included in the metallic layer formation step;

FIG. 9 is a diagram explaining an etching step included in the metallic layer formation step;

FIG. 10 is a diagram explaining a protective film formation step;

FIG. 11 is an enlarged cross section of a part of a semiconductor device according to a second embodiment; and

FIG. 12 is an enlarged cross section of a part of a semiconductor device according to a third embodiment.

### DESCRIPTION OF EMBODIMENTS

Embodiments according to this disclosure will be described with reference to the drawings. In the drawings, some elements may be shown schematically to facilitate understanding. The scope of this disclosure is not limited to the embodiments described below unless the following explanation includes a description that specifically limits the scope of this disclosure.

### 1. Embodiments

### 1-1. Overall Configuration of Semiconductor Device

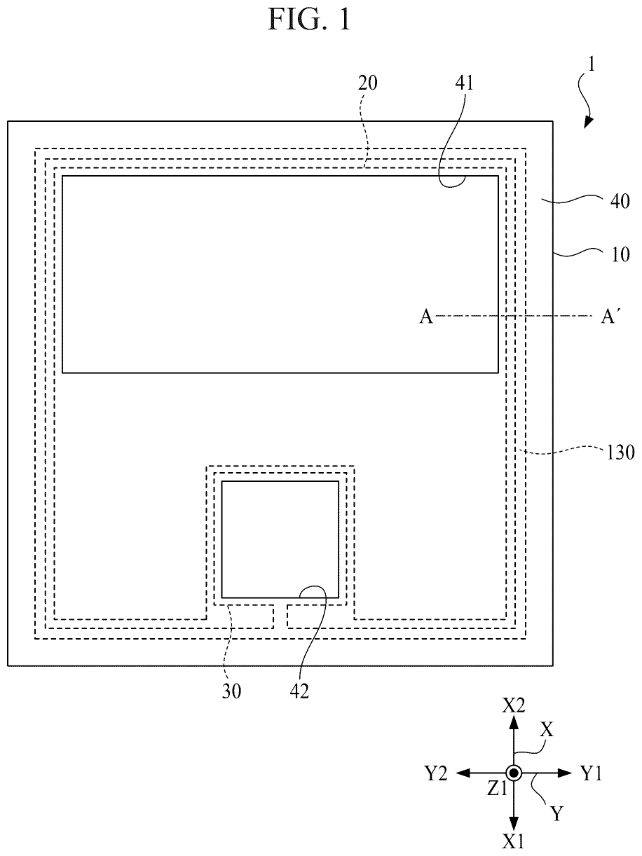

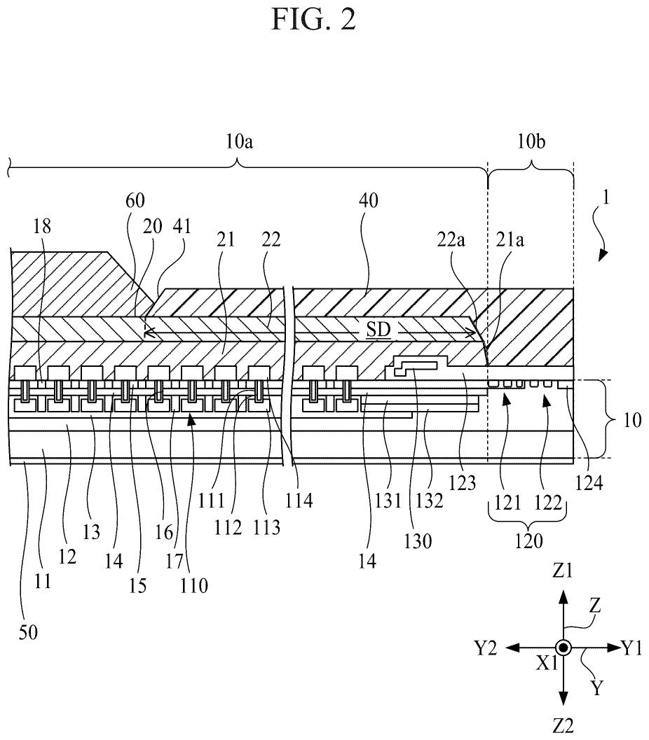

FIG. 1 is a plan view of a semiconductor device 1 according to a first embodiment. FIG. 2 is a cross section taken along line A-A′ shown in FIG. 1, which shows a front surface of the semiconductor device 1. In FIG. 1, a solder material 60 described below is omitted to facilitate visibility.

The semiconductor device 1 includes vertical metal oxide semiconductor field effect transistors (MOSFETs) that each have a trench gate structure, for example. As shown in FIG. 1 and FIG. 2, the semiconductor device 1 includes a semiconductor substrate 10, interlayer insulation films 114 described below, an insulation film 123 described below, a gate runner 130 described below, a source pad 20, a gate pad 30, a protective film 40, and a drain pad 50.

First, an outline of each element of the semiconductor device 1 will be described with reference to FIG. 1 and FIG. 2. In the following description, for convenience, an X-axis, a Y-axis, and a Z-axis are defined that are perpendicular to one another. The Z-axis is an axis parallel to a direction of thickness of the semiconductor device 1. In the following description, a direction along the X-axis is referred to as a direction X1, and a direction opposite to the direction X1 is referred to as a direction X2. A direction along the Y-axis is referred to as a direction Y1, and a direction opposite to the direction Y1 is referred to as a direction Y2. A direction along the Z-axis is referred to as a direction Z1, and a direction opposite to the direction Z1 is referred to as a direction Z2. A relationship between each of these directions and the vertical direction is not particularly limited, and the relationship may be freely selected. In the following description, a view in a direction along the Z-axis may be referred to as “a plan view,” and a surface facing in the direction Z1 may be referred to as “a front surface,” and a surface facing in the direction Z2 may be referred to as “a rear surface.”

The semiconductor substrate 10 is a substrate that is made from a semiconductor such as silicon (Si), silicon carbide (SiC), or gallium nitride (GaN). The semiconductor substrate 10 includes the vertical MOSFETs.

In an example shown in FIG. 1, in plan view, the semiconductor substrate 10 has a shape of a rectangle that has a pair of sides along the X-axis and a pair of sides along the Y-axis. As shown in FIG. 2, the semiconductor substrate 10 is divided into an active region 10a and an edge region 10b.

The active region 10a includes an effective region through which a drift current flows as a main current in a state in which the MOSFETs are turned on. In the example shown in FIG. 1, in plan view, the active region 10a has a shape of a rectangle that is disposed inside an outer edge of the semiconductor substrate 10 and that is along the outer edge of the semiconductor substrate 10.

The active region 10a is provided with a plurality of trenches 16 of the vertical MOSFETs. Between two adjacent trenches 16 among the plurality of trenches 16, an inter-trench p+ region 17 is provided. The active region 10a is provided with a plurality of unit cells 110. Each unit cell 110 of the plurality of unit cells 110 is a region interposed between two adjacent inter-trench p+ regions 17. In FIG. 2, elements such as the vertical MOSFETs provided in the semiconductor substrate 10 are schematically shown, for convenience. In the following description, an example of a configuration of the semiconductor substrate 10 is described with reference to FIG. 1 and FIG. 2. However, the configuration of the semiconductor substrate 10 is not limited to the example shown in FIG. 1 and FIG. 2.

In the following description, “n” and “p” to which “+” is appended each mean a semiconductor region that has a higher impurity concentration compared to a semiconductor region to which “+” is not appended, whereas “n” and “p” to which “−” is appended each mean a semiconductor region that has a lower impurity concentration compared to a semiconductor region to which “−” is not appended. However, an impurity concentration of a semiconductor region to which “n” is appended may not be strictly the same as an impurity concentration of another semiconductor region to which “n” is appended.

The semiconductor substrate 10 at least includes an n+ starting substrate 11, an n− drift layer 12, a p well layer 14, and an n source region 15. The semiconductor substrate 10 may further include an n region 13 and a p++ contact region 18.

The semiconductor substrate 10 is constituted of a stack of the n+ starting substrate 11, the n− drift layer 12, and the n region 13, in this order, in the direction Z1. The p well layer 14 may be formed by ion implantation in which p impurities such as A1 materials are implanted into a front surface of the n region 13. Alternatively, the p well layer 14 may be a p epitaxial layer that is formed on the n region 13. The n source region 15 is formed by ion implantation in which n impurities are implanted into the p well layer 14.

The n+ starting substrate 11 is a substrate made of a semiconductor such as n silicon carbide. The n− drift layer 12 is a layer made of a semiconductor such as n silicon carbide having an impurity concentration lower than that of the n+ starting substrate 11. The n region 13 is a so-called current spreading layer (CSL) having an impurity concentration lower than that of the n+ starting substrate 11 and higher than that of the n− drift layer 12. The n region 13 is not required to be provided. If the n region 13 is not provided, an upper surface of the n− drift layer 12 may be in contact with a lower surface of the p well layer 14.

The p well layer 14 is a layer made of a semiconductor such as p silicon carbide. The p well layer 14 includes a base region. The n source region 15 is a layer made of a semiconductor such as n′ silicon carbide having an impurity concentration lower than that of the n+ starting substrate 11 and higher than that of the n− drift layer 12. The n source region 15 includes a source region.

In the active region 10a, a front surface of the semiconductor substrate 10 is provided with the plurality of trenches 16. The plurality of trenches 16 passes through the p well layer 14 and through the n source region 15. Each of the plurality of trenches 16 has an end in the direction Z2. The end of each of the plurality of trenches 16 in the direction Z2 reaches the n region 13. If the n region 13 is not provided, the end of each of the plurality of trenches 16 in the direction Z2 reaches the n− drift layer 12. Each of the plurality of trenches 16 has a side surface that is in contact with the n source region 15 and with the p well layer 14. The plurality of trenches 16 are aligned with, and are spaced apart from, one another in a direction along the Y-axis. The plurality of trenches 16 may have a stripe-shaped planar pattern extending in a direction along the X-axis. Alternatively, the plurality of trenches 16 may have a dot-shaped planar pattern.

Each of the plurality of trenches 16 has a lower surface and both side surfaces. Along the lower surface and both side surfaces of each of the plurality of trenches 16, a gate insulation film 111 is provided. In each of the plurality of trenches 16, a gate electrode 112 is provided. The gate electrode 112 is surrounded by the gate insulation film 111. The gate insulation film 111 may be constituted of a single-layer film made of any one of: a silicon oxide (SiO₂) film, a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film. Alternatively, the gate insulation film 111 may be constituted of a composite film that is a stack of a plurality of films from among the films described above.

The gate electrode 112 may be constituted of a polysilicon layer (doped polysilicon layer) that is doped with p impurities or with n impurities so as to have a high impurity concentration. Alternatively, the gate electrode 112 may be made of a high-melting-point metal such as titanium (Ti), tungsten (W), or nickel (Ni). The n region 13 is provided with p+ regions 113. If the n region 13 is not provided, the n− drift layer 12 is provided with the p+ regions 113. The end of each of the plurality of trenches 16 in the direction Z2 may be in contact with one of the p+ regions 113. Alternatively, the end of each of the plurality of trenches 16 in the direction Z2 may not be in contact with any one of the p+ regions 113. Below each of the plurality of trenches 16, a p+ region 113 among the p+ regions 113 is provided. The p+ region 113 is a region made of a semiconductor such as p silicon carbide. The p+ region 113 has a function of reducing concentration of an electric field at an end of the gate insulation film 111 in the direction 10) Z2. The p+ region 113 has a width that may be the same as a width of each of the plurality of trenches 16. Alternatively, the width of the p+ region 113 may be greater than the width of each of the plurality of trenches 16. The front surface of the semiconductor substrate 10 is provided with the interlayer insulation films 114 covering the gate electrodes 112. The interlayer insulation films 114 are films made of an insulation material such 15 as phosphorus silicate glass (PSG).

The inter-trench p+ region 17 is provided between two adjacent trenches 16 among the plurality of trenches 16. The inter-trench p+ region 17 is apart from the p+ region 113 and from each of the plurality of trenches 16. The inter-trench p+ region 17 has an upper surface that is in contact with the p well layer 14. The inter-trench p+ region 17 is electrically connected to a first metallic layer 21 via the p well layer 14. The inter-trench p+ region 17 may be constituted of two layers that have an upper inter-trench p+ region 131 and a lower inter-trench p+ region 132. The upper inter-trench p+ region 131 and the lower inter-trench p+ region 132 are adjacent to each other. The upper inter-trench p+ region 131 is formed in a first portion of the n region 13, the first portion of the n region 13 being adjacent to a front surface of the n region 13. The lower inter-trench p+ region 132 is formed in a second portion of the n region 13, the second portion of the n region 13 being adjacent to a lower surface of the n region 13. Alternatively, the inter-trench p+ region 17 may be constituted of a single layer obtained by forming the upper inter-trench p+ region 131 and the lower inter-trench p+ region 132 at the same time.

The p+ region 113 and the inter-trench p+ region 17 each have an electrical potential that is fixed to an electrical potential of the first metallic layer 21. The p+ region 113 and the inter-trench p+ region 17 are depleted when the semiconductor device 1 is turned off, thereby providing an effect of reducing an electric field applied to the gate insulation film 111. The p+ region 113 is spaced apart from the p well layer 14. The p+ region 113 faces a bottom surface of one of the plurality of trenches 16 in a depth direction. The p+ region 113 has a portion (not shown) connected to the inter-trench p+ region 17. Thus, the p+ region 113 is electrically connected to the first metallic layer 21.

In plan view, the edge region 10b is a region between the active region 10a and the outer edge of the semiconductor substrate 10. In the example shown in FIG. 1, the edge region 10b has a shape of a frame that surrounds the active region 10a. The edge region 10b is a region in which neither the p++ contact region 18, the p well layer 14, nor the n source region 15 is provided. The edge region 10b is provided with a withstand-voltage structure 120 that includes a junction termination extension (JTE) structure 121 and a field limiting ring (FLR) structure 122. The withstand-voltage structure 120 has a function of keeping a withstand voltage by reducing an electric field generated in a vicinity of the front surface of the semiconductor substrate 10. The withstand voltage is a maximum voltage that does not cause malfunction of the MOSFETs or damage to the MOSFETs.

In an example shown in FIG. 2, the JTE structure 121 is constituted of p⁻⁻ region that cover a plurality of p⁺⁺ regions with which the front surface of the semiconductor substrate 10 is provided. The plurality of p regions are each provided along an entire circumference of the edge region 10b. The plurality of p⁺⁺ regions are spaced apart from one another. The FLR structure 122 is constituted of a plurality of p⁻⁻ regions with which a part of the front surface of the semiconductor substrate 10 is provided. The part of the front surface of the semiconductor substrate 10 is closer to the outer edge of the semiconductor substrate 10 than the JTE structure 121. The plurality of p⁻⁻ regions are each provided along the entire circumference of the edge region 10b. The plurality of p⁻⁻ regions are spaced apart from each other. The front surface of the semiconductor substrate 10 is provided with the insulation film 123 covering the withstand-voltage structure 120. The insulation film 123 may be formed together with the interlayer insulation films 114 described above. A configuration of the 20) withstand-voltage structure 120 is not limited to the example shown in FIG. 2, and the configuration of the withstand-voltage structure 120 may have one or more of various known structures freely selected as appropriate.

In the semiconductor substrate 10, the n region 13 includes a portion interposed between an outer trench 16 among the plurality of trenches 16 and the edge region 10b, the outer trench being the closest to the edge region 10b among the plurality of trenches 16. In the portion of the n region 13 interposed between the outer trench 16 and the edge region 10b, the p++ contact region 18, the p well layer 14, the upper p+ region 131, and the lower p+ region 132 are provided in this order in the depth direction from the front surface of the semiconductor substrate 10. The p++ contact region 18, the p well layer 14, the upper p+ region 131, the lower p+ region 132 are adjacent to one another, in this order. If the n region 13 is not provided, the p+ contact region 18, the p well layer 14, the upper p+ region 131, and the lower p+ region 132 are provided in this order in the depth direction from the front surface of the semiconductor substrate 10 in a portion of the n− drift layer 12, the portion of the n− drift layer 12 being interposed between the outer trench 16 and the edge region 10b. These regions are formed by extending the p++ contact region 18, the p well layer 14, and the inter-trench 20) p+ region 17 in the active region 10a. The p regions described above may be formed to surround the active region 10a. The p regions described above are regions for extracting a Hall current. The Hall current is generated in the n− drift layer 12 in the edge region 10b when the semiconductor device 1 is turned off, and then the Hall current flows toward a center of the active 25 region 10a. The extracted Hall current flows through the p regions described above to the first metallic layer 21.

The front surface of the semiconductor substrate 10 includes a portion interposed between the outer trench 16 and the withstand-voltage structure 120. Over the portion of the front surface of the semiconductor substrate 10 interposed between the outer trench 16 and the withstand-voltage structure 120, the gate runner 130 is provided via the insulation film 123. The gate runner 130 is provided above the semiconductor substrate 10 so as to surround the active region 10a. The gate runner 130 includes a wiring line made of, for example, polysilicon (Poly-Si). The gate runner 130 may be constituted of a stack structure of the wiring line made of polysilicon and a wiring line made of metal. Although not shown, the gate runner 130 is electrically connected to all of the gate electrodes 112 provided in the active region 10a. The gate runner 130 is electrically connected to the gate pad 30. In other words, the gate runner 130 electrically connects all of the gate electrodes 112 provided in the active region 10a and the gate pad 30 to each other.

In the active region 10a, the source pad 20 and the gate pad 30 are provided over the front surface of the semiconductor substrate 10 via the interlayer insulation films 114.

In the active region 10a, the source pad 20 and the gate pad 30 are each provided on an interlayer insulation film (not shown) over the front surface of the semiconductor substrate 10. The source pad 20 and the gate pad 30 are spaced apart from each other.

The source pad 20 is electrically connected to a base region and a source region constituting a MOS gate, through a contact hole passing through the interlayer insulation film described above. In the example shown in FIG. 1, in plan view, the source pad 20 is provided in an entire region of an opening 41. In plan view, the gate pad 30 is rectangular in shape. The gate pad 30 is provided in an entire region of an opening 42. In plan view, a shape of the source pad 20 and a shape of the gate pad 30 are not limited to the example shown in FIG. 1, and may be freely selected.

The source pad 20 and the gate pad 30 may have the same layer configuration as each other. The source pad 20 and the gate pad 30 may be collectively formed at a common film deposition step. FIG. 2 typically shows a layer configuration of the source pad 20. As shown in FIG. 2, the source pad 20 may include the first metallic layer 21 and a second metallic layer 22. The first metallic layer 21 is provided on the interlayer insulation films 114. The second metallic layer 22 is provided on the first metallic layer 21.

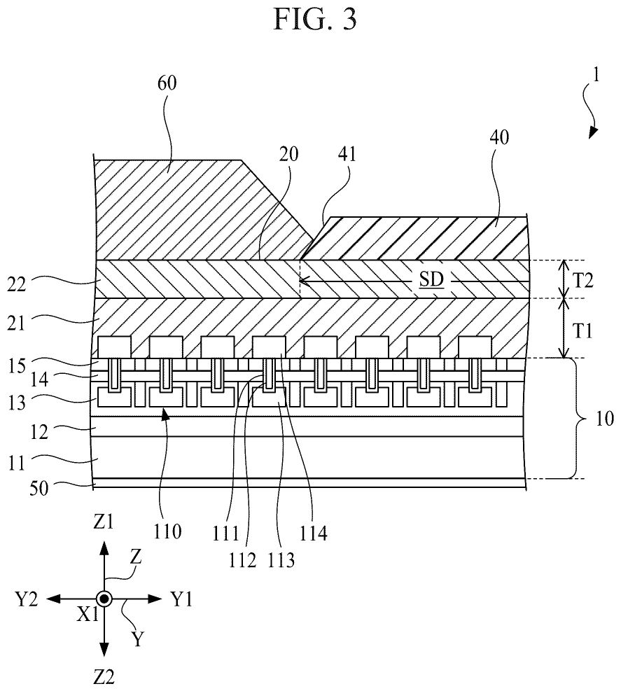

Details of the first metallic layer 21 and the second metallic layer 22 are described below with reference to FIG. 3. As shown in FIG. 2, an outer peripheral surface 21a of the first metallic layer 21 and an outer peripheral surface 22a of the second metallic layer 22 are continuously connected to each other. The outer peripheral surface 21a has a first peripheral edge in the direction Z1 and a second peripheral edge in the direction Z2. In the example shown in FIG. 2, the outer peripheral surface 21a is inclined such that a position of the first peripheral edge on the Y-axis is apart from a position of the second peripheral edge on the Y-axis in the direction Y2. The outer peripheral surface 22a has a third peripheral edge in the direction Z1 and a fourth peripheral edge in the direction Z2. In the example shown in FIG. 2, the outer peripheral surface 22a is inclined such that a position of the third peripheral edge on the Y-axis is apart from a position of the fourth peripheral edge on the Y-axis in the direction Y2. In addition, the outer peripheral surface 21a and the outer peripheral surface 22a are connected to each other such that the first peripheral edge of the outer peripheral surface 21a in the Z1 direction and the fourth peripheral edge of the outer peripheral surface 22a in the direction Z2 coincide with each other. A difference between an inclination angle of the outer peripheral surface 21a and an inclination angle of the outer peripheral surface 22a is caused by a difference in etching rate between a first metallic film 210 and a second metallic film 220 at an etching step S23 described below.

As described above, in plan view, at least a part of an outer edge of the second metallic layer 22 coincides with an outer edge of the first metallic layer 21. The term “coincide” means not only “to be strictly in the same place,” but also “to be substantially in the same place, for example, a state in which a difference caused by manufacturing error, etc., is included. This difference includes a difference caused by the difference in etching rate between the first metallic film 210 and the second metallic film 220 at the etching step S23 described below.

As described above, according to a configuration in which, in plan view, at least a part of the outer edge of the second metallic layer 22 coincides with the outer edge of the first metallic layer 21, compared to a configuration in which the second metallic layer 22 is provided only in a vicinity of the opening 41, it is possible to enhance adhesion between the first metallic layer 21 and the second metallic layer 22. As a result, it is possible to enhance reliability of the semiconductor device 1. When the outer edge of the first metallic layer 21 and the outer edge of the second metallic layer 22 coincide with each other in plan view, the first metallic layer 21 and the second metallic layer 22 can be collectively formed at a common etching step. Thus, compared to a configuration in which the first metallic layer 21 is formed at a first etching step and the second metallic layer 22 is formed at a second etching step different from the first etching step, it is possible to provide the semiconductor device 1 at low cost. In the example shown in FIG. 2, each of the outer peripheral surfaces 21a and 22a is disposed in a vicinity of a boundary between the active region 10a and the edge region 10b.

A part of the source pad 20 covered with the protective film 40 may have a layer configuration different from that of a part of the source pad 20 exposed from the opening 41. For example, between the second metallic layer 22 and the protective film 40, a layer made of metal such as AlSi, which is different from the metal included in the second metallic layer 22, may be interposed. In this case, it is possible to improve adhesion between the second metallic layer 22 and the protective film 40.

On the source pad 20 and the gate pad 30 described above, the protective film 40 is provided. In other words, the protective film 40 is provided over the second metallic layer 22, and the protective film 40 is in contact with the second metallic layer 22. The protective film 40 is made of a resin material such as polyimide.

The protective film 40 includes the opening 41 and the opening 42. The opening 41 passes through the protective film 40 in a direction of thickness of the protective film 40 so as to expose a part of the source pad 20. This allows solder bonding to be achieved by the solder material 60 that is applied to the source pad 20 through the opening 41. The opening 42 passes through the protective film 40 in the direction of thickness of the protective film 40 so as to expose a part of the gate pad 30. This allows solder bonding to be achieved by a solder material that is applied to the gate pad 30 through the opening 42.

The solder material 60 is not particularly limited, and the solder material 60 may be a lead-free solder material such as a SnAg-based solder material, an SnAgCu-based solder material, an SnBi-based solder material, an SnZnBi-based solder material, an SnCu-based solder material, an SnAgBi-based solder material, or an SnZnAl-based solder material.

In plan view, the opening 41 is surrounded by the outer peripheral surface 21a of the first metallic layer 21 and by the outer peripheral surface 22a of the second metallic layer 22, and the opening 41 is spaced apart from the outer peripheral surface 21a and from the outer peripheral surface 22a. Thus, the first metallic layer 21 and the second metallic layer 22 are each provided across a region that includes the opening 41 in plan view. Accordingly, in the opening 41, the first metallic layer 21 is covered with the second metallic layer 22. The second metallic layer 22 includes a part SD interposed between the first metallic layer 21 and the protective film 40.

An entire rear surface of the semiconductor substrate 10 is provided with the drain pad 50 as a drain electrode. The drain pad 50 has a stack structure of a Ti film, a nickel (Ni) film, and a gold (Au) film in this order, for example.

### 1-2. First Metallic Layer and Second Metallic Layer

FIG. 3 is an enlarged cross section of a part of the semiconductor device 1 according to the first embodiment. With reference to FIG. 3, the first metallic layer 21 and the second metallic layer 22 will be described in detail. In the following description, functions and effects obtained by the first metallic layer 21 and the second metallic layer 22 are typically described for the source pad 20. However, the functions and effects obtained by the first metallic layer 21 and the second metallic layer 22 are similarly exerted for the gate pad 30.

As shown in FIG. 3, the second metallic layer 22 has the part SD interposed between the first metallic layer 21 and the protective film 40. Thus, the first metallic layer 21 can be reliably prevented from being exposed from the opening 41 without providing two protective films as described in Japanese Patent Application Laid-Open Publication No. 2019-201160. Consequently, it is possible to prevent contact between the solder material 60 and the first metallic layer 21 due to solder bonding, thereby reducing occurrence of cracks due to thermal stress of the first metallic layer 21. As a result, it is possible to improve reliability of the semiconductor device 1. Two protective films as described in Japanese Patent Application Laid-Open Publication No. 2019-201160 are not required to be provided, thereby simplifying a production process compared to the device described in Japanese Patent Application Laid-Open Publication No. 2019-201160. As a result, it is possible to reduce the cost of the semiconductor device 1.

The first metallic layer 21 may be made of, for example, aluminum (Al) alone. Alternatively, the first metallic layer 21 may be made of an alloy of A1 such as aluminum silicon (AlSi), aluminum silicon copper (AlSiCu), or aluminum copper (AlCu).

In a state in which the first metallic layer 21 is made of A1 or an alloy of A1 as described above, when film deposition conditions is optimized, it is possible to improve embeddability of the first metallic layer 21. Thus, even when the front surface of the semiconductor substrate 10 has unevenness as described above, it is possible to readily flatten the first metallic layer 21.

A thickness T1 of the first metallic layer 21 is not particularly limited as long as the thickness T1 of the first metallic layer 21 is greater than a thickness of each of the interlayer insulation films 114, a thickness of the insulation film 123, and a thickness of the gate runner 130.

The second metallic layer 22 is made of metal different from metal included in the first metallic layer 21. Specifically, the second metallic layer 22 is made of metal to which wettability of the solder material 60 is excellent, for example, nickel (Ni) alone, gold (Au) alone, or an alloy of nickel such as a nickel-phosphorus alloy or a nickel-tin-phosphorus alloy.

When the second metallic layer 22 is made of Ni, an alloy of Ni, or Au as described above, it is possible to improve adhesion between the first metallic layer 21 and the second metallic layer 22 and to improve wettability of the solder material 60 to a part of the second metallic layer 22 that is to be bonded to the solder material 60.

The second metallic layer 22 may be constituted of a single layer or a stack of layers. When the second metallic layer 22 is constituted of a stack of layers, it is preferable that the second metallic layer 22 include both an Ni layer, which is in contact with the first metallic layer 21, and an Au layer, which is provided on this Ni layer, for example. In this case, it is possible to improve the adhesion between the first metallic layer 21 and the second metallic layer 22 and to improve the wettability of the solder material 60 to the portion of the second metallic layer 22 that is to be bonded to the solder material 60.

In this embodiment, it is preferable that a thickness T2 of the second metallic layer 22 be within a range of 1 micrometer or more and 5 micrometers or less. In this case, it is possible to reduce stress due to the second metallic layer 22. In addition, even if a third metallic layer 23 according to a second embodiment is not provided, it is possible to prevent the solder material 60 reaching the first metallic layer 21 due to solder leaching of the second metallic layer 22.

In contrast, when the thickness T2 of the second metallic layer 22 is excessively small, there is a risk that the solder material 60 may reach the first metallic layer 21 due to solder leaching of the second metallic layer 22 depending on materials of the solder material 60, etc. On the other hand, when the thickness T2 of the second metallic layer 22 is excessively large, the stress due to the second metallic layer 22 becomes excessive depending on materials of the second metallic layer 22, etc., and thus problems in production of the semiconductor device 1 are increased.

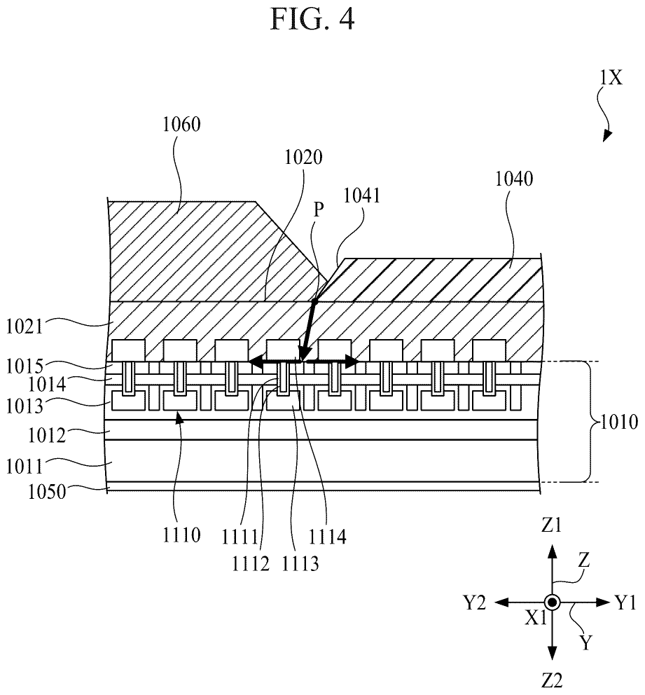

FIG. 4 is an enlarged cross section of a part of a semiconductor device 1X according to a reference example. The semiconductor device 1X has the same configuration as that of the semiconductor device 1 described above, except that the second metallic layer 22 is omitted.

As shown in FIG. 4, in the semiconductor device 1X, a solder material 1060 is provided on a first metallic layer 1021. Thus, at a point Pin a vicinity of an opening 1041 of a protective film 1040, the solder material 1060, the first metallic layer 1021, and the protective film 1040 are in contact with one another. As indicated by arrows shown in FIG. 4, there is a risk that a crack will form in the first metallic layer 1021 by thermal stress due to differences in the linear expansion coefficients of the solder material 1060, the first metallic layer 1021, and the protective film 1040. This crack may easily reach an interface between a semiconductor substrate 1010 and the first metallic layer 1021, thereby reducing reliability of the semiconductor device 1X.

Japanese Patent Application Laid-Open Publication No. 2019-201160 describes a configuration for preventing this crack. In the configuration, an Ni layer is provided on the first metallic layer 1021 in the opening 1041, and an additional protective film made of a resin material such as polyimide is provided on the protective film 1040 so as to cover an outer edge of this Ni layer.

However, in this configuration, a part of the protective film 1040 is interposed between the first metallic layer 1021 and this Ni layer. Thus, there is a risk that this Ni layer may detach from the first metallic layer due to thermal expansion of the protective film 1040. The additional protective film is required in addition to the protective film 1040, thereby complicating a production process. As a result, there is a disadvantage of an increase in cost.

In contrast, in the semiconductor device 1 described above, the first metallic layer 21 can be reliably prevented from being exposed from the opening 41 in a state in which the additional protective film is not provided. Thus, it is possible to prevent contact between the solder material 60 and the first metallic layer 21 in a solder bonding process, thereby reducing occurrence of cracks due to thermal stress of the first metallic layer 21. Consequently, it is possible to enhance power-cycling capability of the semiconductor device 1. Since the protective film 40 is not interposed between the first metallic layer 21 and the second metallic layer 22, it is possible to prevent detachment of the second metallic layer 22 described in Japanese Patent Application Laid-Open Publication No. 2019-201160, thereby improving reliability of the semiconductor device 1. The additional protective film is not required to be provided, thereby simplifying a production process compared to the device described in Japanese Patent Application Laid-Open Publication No. 2019-201160. As a result, it is possible to reduce the cost of the semiconductor device 1.

### 1-3. Method for Producing Semiconductor Device

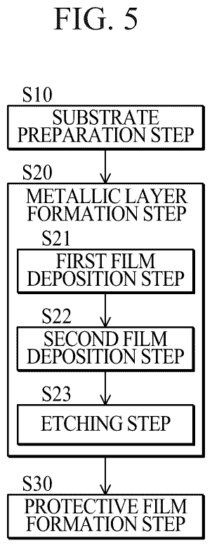

FIG. 5 is a diagram showing a method for producing the semiconductor device 1 according to the first embodiment. As shown in FIG. 5, this method includes a substrate preparation step S10, a metallic layer formation step S20, and a protective film formation step S30, in this order.

At the substrate preparation step S10, over the semiconductor substrate 10, the interlayer insulation films 114, the insulation film 123, and the gate runner 130 made of polysilicon are formed. At the metallic layer formation step S20, the first metallic layer 21 and the second metallic layer 22 are formed. In this embodiment, the metallic layer formation step S20 includes a first film deposition step S21, a second film deposition step S22, and an etching step S23, in this order. At the first film deposition step S21, the first metallic film 210 for the first metallic layer 21 is formed. At the second film deposition step S22, the second metallic film 220 for the second metallic layer 22 is formed. At the etching step S23, the first metallic film 210 and the second metallic film 220 are collectively etched such that the first metallic layer 21 and the second metallic layer 22 are formed. At the protective film formation step S30, the protective film 40 is formed.

Each step will be described in order.

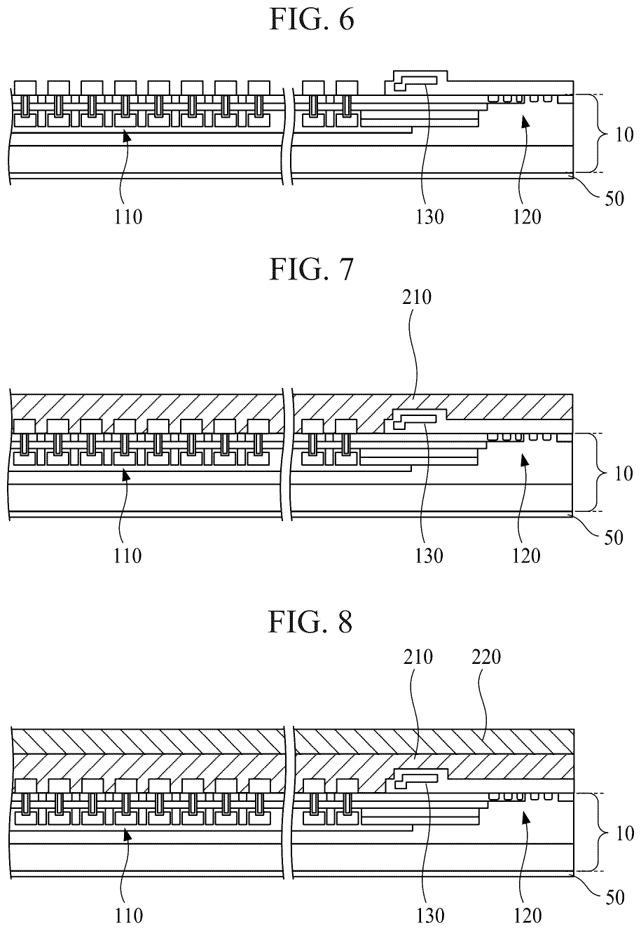

FIG. 6 is a diagram explaining the substrate preparation step S10. As shown in FIG. 6, at the substrate preparation step S10, the semiconductor substrate 10, the interlayer insulation films 114, the insulation film 123, and the gate runner 130 made of polysilicon are formed to be prepared. A method for producing the semiconductor substrate 10 is not particularly limited, and a known method can be used as the method for producing the semiconductor substrate 10. In FIG. 6, the semiconductor substrate 10 includes the drain pad 50. The drain pad 50 may be formed after the substrate preparation step S10.

FIG. 7 is a diagram explaining the first film deposition step S21 included in the metallic layer formation step S20. As shown in FIG. 7, at the first film deposition step S21, the first metallic film 210 is deposited by sputtering, etc., on the semiconductor substrate 10. The first metallic film 210 is a film that is to become the first metallic layer 21 through the etching step S23 described below. The first metallic film 210 is made of, for example, A1 or an alloy of A1. In an example shown in FIG. 7, the first metallic film 210 is formed across an entire region of the front surface on the semiconductor substrate 10.

FIG. 8 is a diagram explaining the second film deposition step S22 included in the metallic layer formation step S20. As shown in FIG. 8, at the second film deposition step S22, the second metallic film 220 is deposited by sputtering on the first metallic film 210. The second metallic film 220 is a film that is to become the second metallic layer 22 through the etching step S23 described below. The second metallic film 220 is made of, for example, Ni, an alloy of Ni, or an Au material. The second metallic film 220 may be made of sputtered solder. The sputtered solder is formed by sputtering using a solder material as a target. In an example shown in FIG. 8, the second metallic film 220 is formed across an entire region of the first metallic film 210.

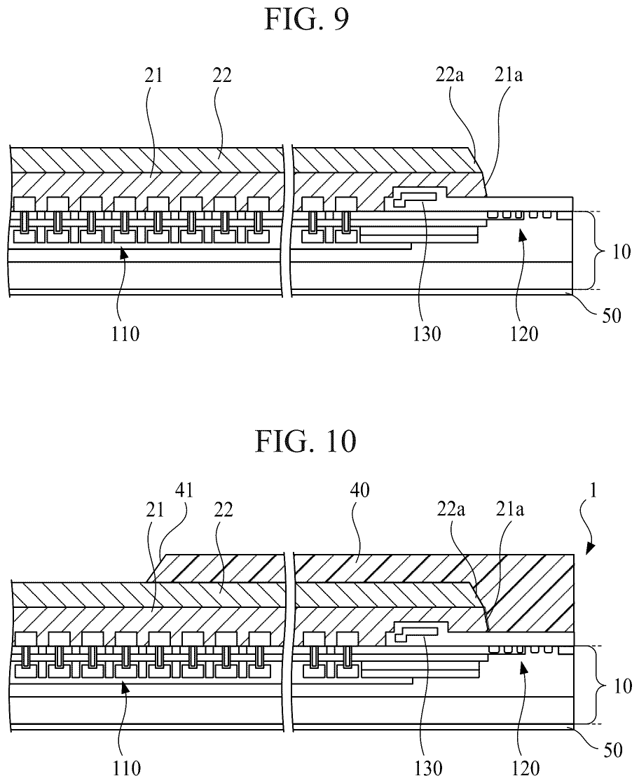

FIG. 9 is a diagram explaining the etching step S23 included in the metallic layer formation step S20. At the etching step S23, the first metallic film 210 and the second metallic film 220 are collectively etched. Thus, as shown in FIG. 9, the first metallic layer 21 and the second metallic layer 22 are formed. An etching method in the etching step S23 is not particularly limited. The etching method in the etching step S23 may be wet etching or dry etching. The etching step S23 is performed in a state in which a photomask is disposed over the second metallic film 220, as appropriate.

At the etching step S23, it is preferable that an etching rate of the second metallic film 220 be higher than an etching rate of the first metallic film 210. In this manner, as described above, the outer peripheral surface 21a has the first peripheral edge in the direction Z1 and the second peripheral edge in the direction Z2, and the outer peripheral surface 21a is inclined such that the position of the first peripheral edge on the Y-axis is apart from the position of the second peripheral edge on the Y-axis in the direction Y2. In addition, as described above, the outer peripheral surface 22a has the third peripheral edge in the direction Z1 and the fourth peripheral edge in the direction Z2, and the outer peripheral surface 22a is inclined such that the position of the third peripheral edge on the Y-axis is apart from the position of the fourth peripheral edge on the Y-axis in the direction Y2. As a result, at the protective film formation step S30, the protective film 40 can be readily brought into close contact with the first metallic layer 21 and with the second metallic layer 22 without a gap.

FIG. 10 is a diagram explaining the protective film formation step S30. As shown in FIG. 10, at the protective film formation step S30, the protective film 40 is formed. Specifically, at the protective film formation step S30, after a polyimide film is formed across an entire region of the front surface of the semiconductor substrate 10, this polyimide film is selectively removed by photolithography and by etching, for example. Thus, the protective film 40 having the opening 41 is formed.

After that, although not shown, the semiconductor substrate 10 is divided by dicing into chips, and then the solder material 60 is formed on the second metallic layer 22 in the opening 41 such that the source pad 20 is solder-bonded to a terminal, etc. In this manner, the semiconductor device 1 is obtained.

According to the method for producing the semiconductor device 1 as described above, it is possible to produce the semiconductor device 1 having high reliability at low cost. As described above, in this embodiment, the metallic layer formation step S20 includes the first film deposition step S21, the second film deposition step S22, and the etching step S23. Thus, it is possible to reduce a production cost of the semiconductor device 1 compared to a method in which the first metallic film 210 and the second metallic film 220 are individually etched.

### 2. Second Embodiment

A second embodiment according to this disclosure will be described. In the description of the following embodiment, elements having the same operations and the same functions as in the embodiment described above are denoted by the same reference numerals used for like elements in the description of the embodiment, and detailed description thereof is omitted, as appropriate.

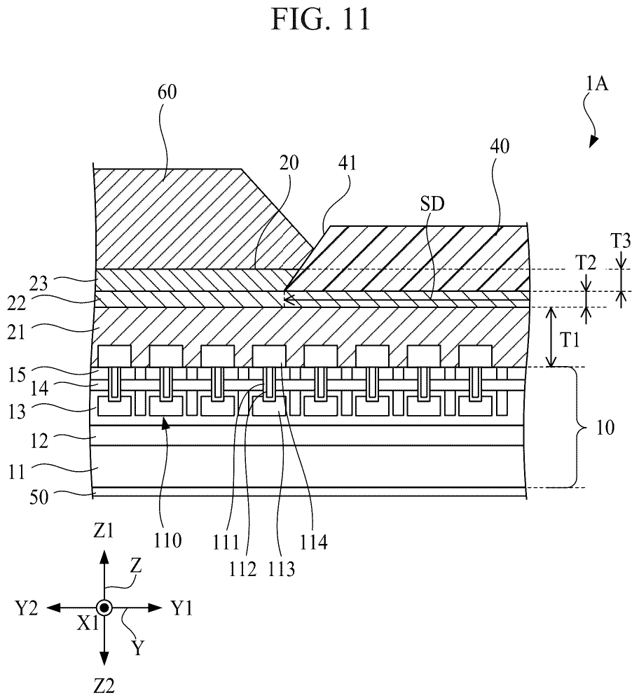

FIG. 11 is an enlarged cross section of a part of a semiconductor device 1A according to the second embodiment. The semiconductor device 1A has the same configuration as that of the semiconductor device 1 according to the first embodiment, except that the third metallic layer 23 described above is added.

The third metallic layer 23 is provided on the second metallic layer 22. In plan view, the third metallic layer 23 is disposed in the opening 41. The third metallic layer 23 is made of, for example, nickel (Ni) alone, an alloy of nickel such as a nickel-phosphorus alloy or a nickel-tin-phosphorus alloy, or gold (Au) alone. It is preferable that the third metallic layer 23 be made of gold (Au). The third metallic layer 23 is formed by plating. The material included in the third metallic layer 23 may be the same as, or be different from, the material included in the second metallic layer 22.

As described above, the semiconductor device 1A includes the third metallic layer 23. Thus, it is possible to improve wettability of the solder material 60 to a portion of the third metallic layer 23 that is to be bonded to the solder material 60. In addition, with the third metallic layer 23 being provided, it is possible to reduce the thickness T2 of the second metallic layer 22.

In this embodiment, it is preferable that the thickness T2 of the second metallic layer 22 be within a range of 1 micrometer or more and 2 micrometers or less. In this case, even when the third metallic layer 23 is provided, it is possible to reduce total stress due to the second metallic layer 22 and the third metallic layer 23, and to prevent the solder material 60 reaching the first metallic layer 21 due to solder leaching of the second metallic layer 22 and due to solder leaching of the third metallic layer 23.

It is preferable that a thickness T3 of the third metallic layer 23 be within a range of 0.1 micrometers or more and 1 micrometer or less. In this case, even when the third metallic layer 23 is provided, it is possible to reduce total stress due to the second metallic layer 22 and the third metallic layer 23, and to prevent the solder material 60 reaching the first metallic layer 21 due to solder leaching of the second metallic layer 22 and due to solder leaching of the third metallic layer 23.

According to the second embodiment described above, it is possible to improve reliability of the semiconductor device 1A at low cost.

### 3. Third Embodiment

A third embodiment according to this disclosure will be described. In the description of the following embodiment, elements having the same operations and the same functions as in the embodiment described above are denoted by the same reference numerals used for like elements in the description of the embodiment, and detailed description thereof is omitted, as appropriate.

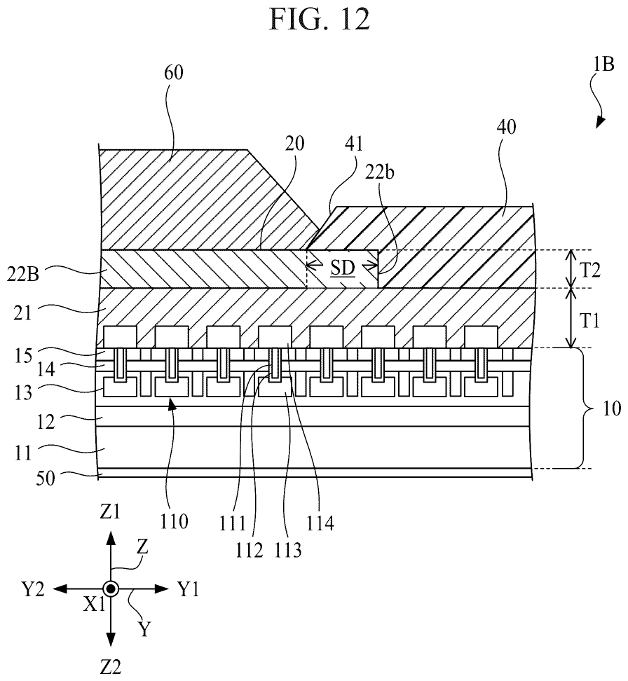

FIG. 12 is an enlarged cross section of a part of a semiconductor device 1B according to the third embodiment. The semiconductor device 1B has the same configuration as that of the semiconductor device 1 according to the first embodiment, except that a second metallic layer 22B is included in place of the second metallic layer 22.

The second metallic layer 22B has the same configuration as that of the second metallic layer 22 according to the second embodiment, except that a through hole 22b is included. In plan view, the through hole 22b of the second metallic layer 22B overlaps with the protective film 40. Thus, a part of the protective film 40 enters the through hole 22b. Consequently, it is possible to enhance adhesion between the protective film 40 and the second metallic layer 22B by anchor effect. As a result, it is possible to further enhance the reliability of the semiconductor device 1B.

As long as the through hole 22b is covered with the protective film 40, modes of the through hole 22b, such as a shape of the through hole 22b, a position of the through hole 22b, a size of the through hole 22b, and a range of the through hole 22b, are not particularly limited, and may be freely selected.

According to the third embodiment described above, it is possible to improve reliability of the semiconductor device 1B at low cost.

### 4. Modifications

This disclosure is not limited to the embodiments described above, and various modifications described below can be made thereto. In addition, each of the embodiments and each of the modifications may be combined with others as appropriate.

### 4-1. First Modification

For example, the second embodiment and the third embodiment may be combined with each other. In other words, in the second embodiment, the second metallic layer 22B according the third embodiment may be provided in place of the second metallic layer 22. In the third embodiment, the semiconductor device 1B may include the third metallic layer 23 according to the second embodiment.

### 4-2. Second Modification

In each of the embodiments described above, a configuration is described in which the source pad 20 and the gate pad 30 each include the first metallic layer 21 and the second metallic layer 22. However, this disclosure is not limited thereto. When the semiconductor device includes a diode, a pad for the diode may have the same configuration as that of each of the source pad 20 and the gate pad 30 described above.

### DESCRIPTION OF REFERENCE SIGNS

1 . . . semiconductor device, 1A . . . semiconductor device, 1B . . . semiconductor device, 1X . . . semiconductor device, 10 . . . semiconductor substrate, 10a . . . active region, 10b . . . edge region, 11 . . . n+ starting substrate, 12 . . . drift layer, 13 . . . n region, 14 . . . p well layer, 15 . . . n source region, 16 . . . trench, 20 . . . source pad, 21 . . . first metallic layer, 21a . . . outer peripheral surface, 22 . . . second metallic layer, 22B . . . second metallic layer, 22a . . . outer peripheral surface, 22b . . . through hole, 23 . . . third metallic layer, 30 . . . gate pad, 40 . . . protective film, 41 . . . opening, 42 . . . opening, 50 . . . drain pad, 60 . . . solder material, 110 . . . unit cell, 111 . . . gate insulation film, 112 . . . gate electrode, 113 . . . p region, 114 . . . interlayer insulation film, 120 . . . withstand-voltage structure, 121 . . . . JTE structure, 122 . . . . FLR structure, 123 . . . insulation film, 130 . . . gate runner, 131 . . . p region, 210 . . . first metallic film, 220 . . . second metallic film, P . . . point, SD . . . part, S10 . . . substrate preparation step, S20 . . . metallic layer formation step, S21 . . . first film deposition step, S22 . . . second film deposition step, S23 . . . etching step, S30 . . . protective film formation step, T1 . . . thickness, T2 . . . thickness, T3 . . . thickness.

What is claimed is:

1. A semiconductor device comprising:
a semiconductor substrate;
a first metallic layer provided over the semiconductor substrate;
a second metallic layer provided on the first metallic layer; and
a protective film including an opening, the protective film being provided on the second metallic layer,
wherein the protective film is in contact with the second metallic layer, and is made of a resin material,
wherein the first metallic layer and the second metallic layer are each provided across a region that includes the opening in plan view, and
wherein the second metallic layer has a part interposed between the first metallic layer and the protective film.

2. The semiconductor device according to claim 1, wherein, in plan view, at least a part of an outer edge of the second metallic layer coincides with an outer edge of the first metallic layer.

3. The semiconductor device according to claim 1, wherein, the second metallic layer includes a through hole that overlaps with the protective film in plan view.

4. The semiconductor device according to claim 1, wherein the second metallic layer is made of Ni, an alloy of Ni, or Au.

5. The semiconductor device according to claim 4, wherein the second metallic layer has a thickness that is within a range of 1 micrometer or more and 5 micrometers or less.

6. The semiconductor device according to claim 4,
further comprising a third metallic layer provided on the second metallic layer, the third metallic layer being disposed in the opening in plan view,
wherein the third metallic layer is made of Ni, an alloy of Ni, or Au.

7. The semiconductor device according to claim 6, wherein the second metallic layer has a thickness that is within a range of 1 micrometer or more and 2 micrometers or less.

8. The semiconductor device according to claim 6, wherein the third metallic layer has a thickness that is within a range of 1 micrometer or more and 3 micrometers or less.

9. The semiconductor device according to claim 4, wherein the first metallic layer is made of A1 or an alloy of A1.

10. A method for producing a semiconductor device, the semiconductor device including:
a semiconductor substrate;
a first metallic layer provided over the semiconductor substrate;
a second metallic layer provided on the first metallic layer; and
a protective film including an opening, the protective film being provided on the second metallic layer,
the method comprising:
forming the first metallic layer and the second metallic layer; and
forming the protective film,
wherein the protective film is in contact with the second metallic layer, and is made of a resin material,
wherein the first metallic layer and the second metallic layer are each provided across a region that includes the opening in plan view, and
wherein the second metallic layer has a part interposed between the first metallic layer and the protective film.

11. The method according to claim 10, wherein the forming of the first metallic layer and the second metallic layer includes:
depositing a first metallic film over the semiconductor substrate;
depositing a second metallic film on the first metallic film; and
collectively etching the first metallic film and the second metallic film to form the first metallic layer and the second metallic layer.
